(19) United States
(12) Patent Application Publication
(10) Pub. No.: US 2026/0180548 A1
(43) Pub. Date: Jun. 25, 2026

(54) Acoustic Wave Device and Module

(71) Applicant: Sanan Japan Technology Corporation, Kanagawa (JP)

(72) Inventors: Yuki Koto, Kanagawa (JP); Shinichi SHIOI, Kanagawa (JP)

(21) Appl. No.: 19/430,281

(22) Filed: Dec. 23, 2025

(30) Foreign Application Priority Data
Dec. 24, 2024 (JP) 2024-227446

(51) Int. Cl. H03H 9/05; H03H 9/64

(52) U.S. Cl. CPC H03H 9/059; H03H 9/6483

(57) ABSTRACT

An acoustic wave device is disclosed, which includes a package substrate sequentially including a mounting surface, a first inner layer, a second inner layer, and an external connection surface; a device chip is disposed on the mounting surface via a plurality of bumps, wherein the plurality of bumps include a heat-dissipation bump; a plurality of resonators formed on the device chip and constituting a ladder-type filter; the mounting surface provided with a plurality of metal patterns, including a heat-dissipation pad connected to the heat-dissipation bump; the first inner layer provided with a plurality of metal patterns, including a first metal pattern electrically connected to the heat-dissipation pad via a via; the second inner layer provided with a plurality of metal patterns, including a second metal pattern electrically connected to the first metal pattern via a via.

### CROSS-REFERENCE TO RELATED APPLICATION

The present disclosure claims priority to Japanese Patent Application No. 2024-227446 filed December 24, 2024, the contents of which are herein incorporated by reference in its entirety.

### FIELD

This application relates to the field of mobile communication devices and, more particularly, to an acoustic wave device.

### BACKGROUND

With recent technological advances, mobile communication terminals, typified by smartphones, have been remarkably miniaturized and reduced in weight. As acoustic wave devices used in such mobile communication terminals, acoustic wave devices that can be miniaturized are employed.

With miniaturization, ensuring the power durability of acoustic wave devices has become more stringent. That is, a structure with superior heat dissipation compared to the prior art is required.

In order to improve the heat dissipation of acoustic wave devices, for example, Patent Document 1(JP 2019-4264A) discloses a technique of improving heat dissipation from a device chip including a piezoelectric substrate to the package substrate side by using dummy bumps.

However, in the acoustic wave device described in Patent Document 1, the heat dissipation is not sufficient.

### SUMMARY

Some examples described herein may have an object to provide an acoustic wave device with improved heat dissipation and a module including the acoustic wave device.

In some examples, an acoustic wave device is provided, which comprises: a package substrate; a device chip disposed on a mounting surface of the package substrate via a plurality of bumps; and a heat-dissipation pad connected to at least one of the plurality of bumps.

In some examples, a communication module includes the above-mentioned acoustic wave device.

According to the present invention, the heat dissipation of the acoustic wave device can be improved.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a longitudinal sectional view of an acoustic wave device 20 in Embodiment 1.

FIG. 2 is a diagram showing an example of an acoustic wave element (resonator) of the acoustic wave device 20 in Embodiment 1.

FIG. 3 is a diagram showing an example of the acoustic wave device 20 in Embodiment 1.

FIG. 4 is a top view showing the configuration of each layer of the package substrate of the acoustic wave device 20 in Embodiment 1.

FIG. 5 is a top view showing the configuration of each layer of a package substrate of a comparative example of the acoustic wave device 20 in Embodiment 1.

FIG. 6 is a diagram showing transmission characteristics of the acoustic wave device 20 in Embodiment 1.

FIG. 7 is a diagram showing an example of the acoustic wave device 20 in Embodiment 2.

FIG. 8 is a top view showing the configuration of each layer of the package substrate of the acoustic wave device 20 in Embodiment 2.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### Embodiment 1

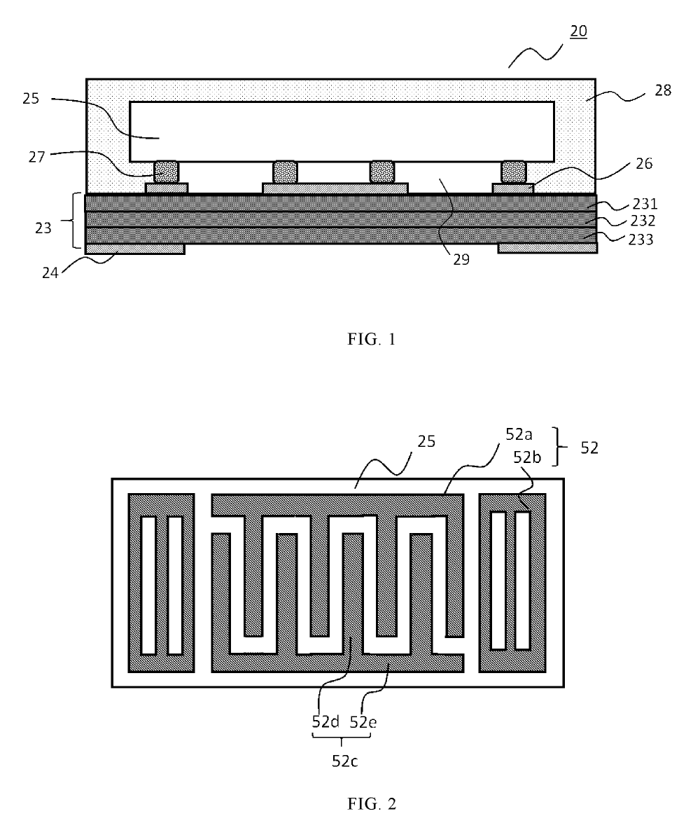

FIG. 1 is a longitudinal sectional view of an acoustic wave device 20 according to Embodiment 1.

As shown in FIG. 1, the acoustic wave device 20 comprises a package substrate 23, external connection terminals 24, a device chip 25, electrode pads 26, bumps 27, and a sealing portion 28.

For example, the package substrate 23 is a multilayer substrate made of resin. In one example, the package substrate 23 is a multilayer substrate of low-temperature co-fired ceramics (LTCC) composed of a plurality of dielectric layers.

A plurality of external connection terminals 24 are formed on the lower surface of the package substrate 23.

A plurality of electrode pads 26 are formed on the main surface of the package substrate 23, i.e., on the mounting surface of the device chip 25. For example, each electrode pad 26 is formed of copper or an alloy containing copper. The thickness of the electrode pad 26 may, for instance, be in the range of 10 µm to 20 µm.

For example, the package substrate 23 includes a first substrate 231, a second substrate 232, and a third substrate 233, and may include additional laminated substrates. Although not illustrated in FIG. 1, a plurality of metal patterns are formed between the first substrate 231 and the second substrate 232 and are electrically connected to the electrode pads 26 via vias penetrating the first substrate 231.

Although not illustrated in FIG. 1, a plurality of metal patterns are also formed between the second substrate 232 and the third substrate 233 and are electrically connected to the plurality of metal patterns formed between the first substrate 231 and the second substrate 232 via vias penetrating the second substrate 232.

The bumps 27 are formed on the upper surfaces of the respective electrode pads 26. For example, each bump 27 is a gold bump. The height of each bump 27 may, for example, be in the range of 10 µm to 50 µm.

The device chip 25 is mounted on the package substrate 23 by flip-chip bonding through the bumps 27. The device chip 25 is electrically connected to the plurality of electrode pads 26 via the plurality of bumps 27.

The device chip 25 is, for example, a surface acoustic wave (SAW) device chip. The device chip 25 includes a piezoelectric substrate formed of a piezoelectric material. The piezoelectric substrate is a substrate formed of a piezoelectric single crystal such as lithium tantalate (LiTaO₃), lithium niobate (LiNbO₃), or quartz.

The thickness of the piezoelectric substrate may be, for example, from 100 µm to 300 µm. In another example, the piezoelectric substrate may be a substrate formed of piezoelectric ceramics.

In another example, the device chip 25 is a substrate in which the piezoelectric substrate and a support substrate are joined directly or indirectly through an intermediate layer. The support substrate may be formed of sapphire, silicon, alumina, spinel, quartz, or glass. In this case, the thickness of the piezoelectric substrate may, for example, be in the range of 0.3 µm to 5 µm.

An acoustic wave element is formed on the piezoelectric substrate. For example, a band-pass filter including a plurality of acoustic wave elements are formed on the main surface of the device chip 25.

In another example, a duplexer including a transmission filter and a reception filter is formed on the main surface of the device chip 25.

The transmission filter is configured so that electric signals in a desired frequency band can pass therethrough. For example, the transmission filter is a ladder-type filter composed of a plurality of series resonators and a plurality of parallel resonators.

The reception filter is configured so that electric signals in a desired frequency band can pass therethrough. For example, the reception filter is a ladder-type filter.

The sealing portion 28 is formed so as to cover the device chip 25. For example, the sealing portion 28 is formed of an insulating material such as synthetic resin. Alternatively, the sealing portion 28 may be formed of metal.

When the sealing portion 28 is formed of synthetic resin, the resin may be an epoxy resin or a polyimide. Preferably, the sealing portion 28 is formed of an epoxy resin using a low-temperature curing process.

A cavity 29 is formed in a region where the package substrate 23 faces the device chip 25. This ensures a space for mechanical vibration of the acoustic wave elements.

Next, an example of the acoustic wave element 52 formed on the device chip 25 will be described with reference to FIG. 2. FIG. 2 is a diagram showing an example of an acoustic wave element (resonator) of the acoustic wave device 20 according to Embodiment 1.

As shown in FIG. 2, an interdigital transducer (IDT) electrode 52a and a pair of reflectors 52b are formed on the main surface of the device chip 25. The IDT electrode 52a and the pair of reflectors 52b are provided so as to excite acoustic waves, primarily shear-horizontal (SH) waves.

For example, the IDT electrode 52a and the pair of reflectors 52b are formed of an alloy of aluminum and copper. Alternatively, the IDT electrode 52a and the pair of reflectors 52b may be formed of a suitable metal or an alloy thereof, or a laminate thereof, such as aluminum, copper, platinum, molybdenum, iridium, tungsten, cobalt, nickel, ruthenium, chromium, strontium, titanium, palladium, or silver.

For example, the IDT electrode 52a and the pair of reflectors 52b are formed of a laminated metal film composed of a plurality of stacked metal layers. The thickness of the IDT electrode 52a and the pair of reflectors 52b may be in the range of 150 nm to 450 nm.

The IDT electrode 52a includes a pair of comb-shaped electrodes 52c. The pair of comb-shaped electrodes 52c are arranged to face each other. Each comb-shaped electrode 52c includes a plurality of electrode fingers 52d and a bus bar 52e.

The plurality of electrode fingers 52d are arranged with their longitudinal directions aligned. The bus bar 52e connects the plurality of electrode fingers 52d.

One of the pair of reflectors 52b is disposed adjacent to one side of the IDT electrode 52a, and the other of the pair of reflectors 52b is disposed adjacent to the other side of the IDT electrode 52a.

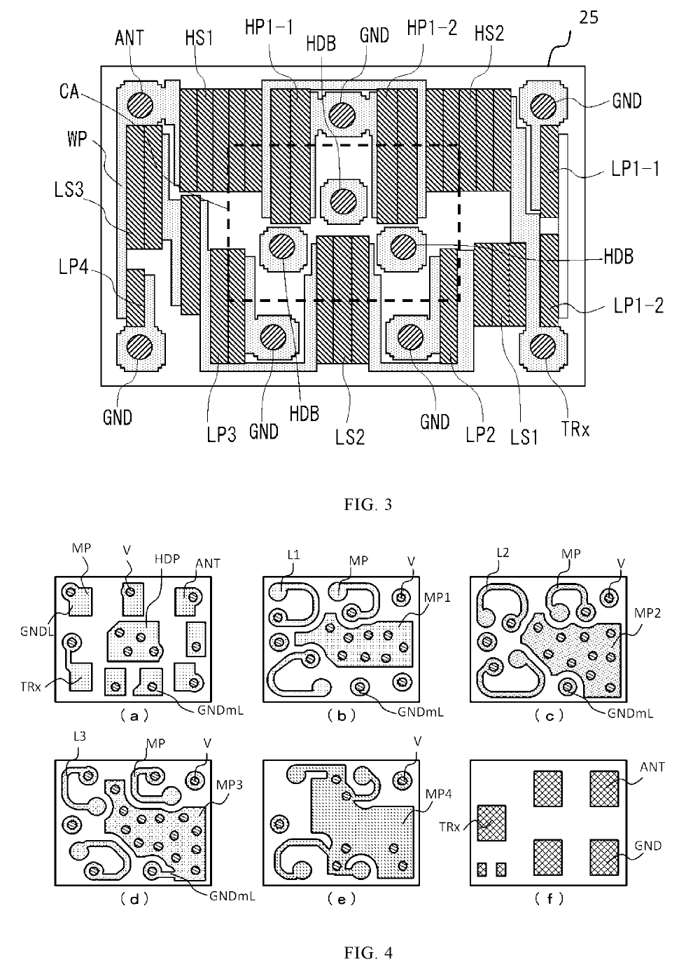

Next, an example of a band-pass filter formed on the device chip 25 will be described with reference to FIG. 3. FIG. 3 is a diagram showing an example of the acoustic wave device 20 according to Embodiment 1.

As shown in FIG. 3, a plurality of resonators, a plurality of bumps 27, and wiring patterns WP are formed on the device chip 25. In FIG. 3, circuit functional symbols are additionally provided as reference characters for each bump.

Some of the plurality of resonators form a high-frequency side passband as multiple series resonators HS1 and HS2 and multiple parallel resonators HP1-1 and HP1-2. Other resonators form a low-frequency side passband as multiple series resonators LS1, LS2, and LS3, and multiple parallel resonators LP1-1, LP1-2, LP2, LP3, and LP4. The high-frequency side passband and the low-frequency side passband together constitute a band-pass filter.

Some of the plurality of bumps 27 serve as heat dissipation bumps HDB. As indicated by the dotted-line region in FIG. 3, the heat dissipation bumps HDB are disposed in a central region CA of the device chip 25. The heat dissipation bumps HDB are arranged such that they are surrounded by multiple resonators, for example, by resonators HP1-1, HP1-2, and LS2.

In another example, other heat dissipation bumps HDB are arranged such that they are surrounded by resonators HP1-1, LP3, and LS2. The heat dissipation bumps HDB are positioned in the central region CA because heat generated by excitation of the resonators tends to accumulate in this area.

Each of the heat dissipation bumps HDB shown in FIG. 3 is not electrically connected to any other metal pattern on the device chip 25. However, depending on the adopted circuit configuration, the heat dissipation bumps HDB may be electrically connected to other metal patterns on the device chip 25.

The wiring patterns WP are wirings that electrically connect the plurality of resonators to one another and/or electrically connect the plurality of resonators to the bumps.

FIG. 4 is a top view showing the layer configuration of the package substrate 23 of the acoustic wave device 20 according to Embodiment 1. FIGS. 4(b) to 4(f) are top views as viewed in the vertical direction of the plane shown in FIG. 4(a). The vias V formed from FIGS. 4(a) to 4(e) electrically connect corresponding positions of the metal patterns in FIGS. 4(b) to 4(f). For example, the via V shown in FIG. 4(a) electrically connects the metal pattern in FIG. 4(a) with that in FIG. 4(b). Here, the term “metal pattern (MP)” comprehensively refers to patterned metal features such as the heat dissipation pad HDP, antenna pad ANT, transmit/receive pad TRx, ground pads, and inductor patterns, which will be described later.

FIG. 4(a) shows the configuration of the mounting surface of the package substrate 23. The device chip 25 is flip-chip bonded to the mounting surface via multiple bumps. As shown in FIG. 4(a), a total of nine metal patterns MP are formed on the mounting surface. The plurality of metal patterns MP include a heat dissipation pad HDP, which has the largest area among the metal patterns.

The mounting surface also includes an antenna pad ANT, a transmit/receive pad TRx, and pads connected to ground. Since the layout of the device chip 25 shown in FIG. 3 is flip-chip bonded, the TRx and ANT terminals in FIG. 3 are inverted and bonded via bumps to the transmit/receive pad TRx and the antenna pad ANT shown in FIG. 4(a), respectively.

FIG. 4(b) shows the configuration of the metal patterns MP in the first inner layer (the innermost layer closest to the mounting surface). Eight metal patterns MP are formed in the first inner layer. The first inner layer includes a first metal pattern MP1. As shown in FIG. 4(b), the first metal pattern MP1 is the largest metal pattern in area within the first inner layer.

With reference to FIGS. 4(a) and 4(b), the heat dissipation pad HDP and the first metal pattern MP1 are electrically connected by four vias V. The first metal pattern MP1 has a larger area than the heat dissipation pad HDP. In addition, three inductor patterns are formed in the first inner layer, and each is electrically connected to corresponding pads via the vias V.

It is preferable that only the heat dissipation bumps HDB are connected to the heat dissipation pad HDP.

FIG. 4(c) shows the configuration of the metal patterns MP in the second inner layer as viewed from the mounting surface side. Seven metal patterns MP are formed in the second inner layer. The second inner layer includes a second metal pattern MP2. As shown in FIG. 4(c), the second metal pattern MP2 is the largest metal pattern in area within the second inner layer.

With reference also to FIG. 4(b), the second metal pattern MP2 and the first metal pattern MP1 are electrically connected by eight vias V. The second metal pattern MP2 has a larger area than the first metal pattern MP1. Furthermore, three inductor patterns are formed in the second inner layer. Each inductor pattern is electrically connected to the corresponding inductor pattern in FIG. 4(b) via the vias V.

FIG. 4(d) shows the configuration of the metal patterns MP in the third inner layer as viewed from the mounting surface side. Six metal patterns MP are formed in the third inner layer. The third inner layer includes a third metal pattern MP3. As shown in FIG. 4(d), the third metal pattern MP3 is the largest metal pattern in area within the third inner layer.

With reference also to FIG. 4(c), the third metal pattern MP3 and the second metal pattern MP2 are electrically connected by ten vias V. In addition, four inductor patterns are formed in the third inner layer. Each inductor pattern is electrically connected to the corresponding inductor pattern in FIG. 4(c) via the vias V.

FIG. 4(e) shows the configuration of the metal patterns MP in the fourth inner layer as viewed from the mounting surface side. Three metal patterns MP are formed in the fourth inner layer, including a fourth metal pattern MP4. With reference also to FIG. 4(d), the fourth metal pattern MP4 and the third metal pattern MP3 are electrically connected by fourteen vias V. The fourth metal pattern MP4 is also electrically connected to each inductor pattern in the third inner layer via the vias V.

FIG. 4(f) is a top view showing the configuration of the external connection terminals 24 of the package substrate 23. The external connection terminals include a transmit/receive terminal TRx, an antenna terminal ANT, and a ground terminal GND.

Here, the heat dissipation pad HDP, the first metal pattern MP1, the second metal pattern MP2, and the third metal pattern MP3 become the ground potential of the acoustic wave device only after they are electrically connected to the metal pattern MP of the third or fourth inner layer. Until such a connection is established, they consist solely of large metal patterns. The inventors have found that by stacking multiple large metal patterns in the vertical (lamination) direction without interposing inductor patterns or wiring patterns between the heat dissipation bumps HDB, a package substrate having high heat dissipation performance can be achieved.

In order to secure ground inductance in a ladder-type filter, inductor patterns are often provided in the package substrate 23. However, since the area of the inductor pattern is small and the number of vias is limited, the heat dissipation is insufficient. In addition, heat tends to accumulate in the central region of the device chip.

Accordingly, by providing heat dissipation bumps HDB in the central region of the device chip, disposing a large-area metal pattern as a heat dissipation pad, and stacking multiple large metal patterns in the lamination direction without interposing inductor patterns or the like, while providing numerous thermally conductive vias between layers, it was found that the heat dissipation performance can be significantly improved.

Furthermore, taking into account that heat diffuses radially, the area of the first metal pattern MP1 is made larger than that of the heat dissipation pad HDP, and the area of the second metal pattern MP2 is made larger than that of the first metal pattern MP1, thereby adopting a structure conforming to the natural law of heat diffusion.

For the same reason, it is desirable to increase the number of vias connecting the first metal pattern MP1 and the second metal pattern MP2, compared to the number of vias connecting the heat dissipation pad HDP and the first metal pattern MP1, so as to achieve a structure consistent with the natural law of heat diffusion.

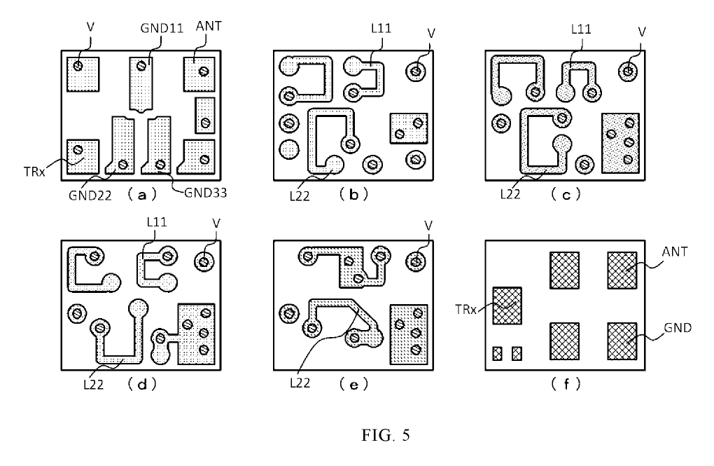

Next, a comparative example of the acoustic wave device 20 in Embodiment 1 will be described. In the comparative example, the same device chip 25 as in Embodiment 1 was used. FIG. 5 is a plan view showing the configuration of each layer of the package substrate in the comparative example of the acoustic wave device 20 in Embodiment 1. FIGS. 5(b) to 5(f) are plan views seen in perspective in the vertical direction of the plane shown in FIG. 5(a).

FIG. 5(a) is a diagram showing the configuration of the mounting surface of the package substrate in the comparative example of the acoustic wave device 20. As shown in FIG. 5(a), although a plurality of ground pads GND are formed on the mounting surface, the heat dissipation pad HDP in Embodiment 1 is not included. That is, in the comparative example, each heat dissipation bump is bonded to each of the ground pads GND11, GND22, and GND33.

FIG. 5(b) is a diagram showing the configuration of the metal patterns in the first inner layer (the first inner layer of the comparative example) as viewed from the mounting-surface side. Inductor patterns L11 and L22 are formed in the first inner layer of the comparative example. The inductor pattern L11 is electrically connected to the ground pad GND11 in FIG. 5(a) via vias V. The inductor pattern L22 is electrically connected to the ground pad GND22 in FIG. 5(a) via vias V.

As shown in FIGS. 5(c) to 5(e), which depict the configurations of the metal patterns from the second inner layer (the second inner layer of the comparative example) to the fourth inner layer (the fourth inner layer of the comparative example) as viewed from the mounting-surface side, the inductor pattern L11 is formed so as to extend across the third inner layer of the comparative example. The inductor pattern L22 is formed so as to extend across the fourth inner layer of the comparative example. Since the configuration of FIG. 5(f) is the same as that of FIG. 4(f), description thereof is omitted.

Thermal analysis of the acoustic wave device 20 of Embodiment 1 revealed that the temperature at the hottest point on the device chip was 84.5° C. Next, thermal analysis of the comparative acoustic wave device showed that the temperature at the hottest point on the device chip was 99.9° C. In other words, in the acoustic wave device 20 of Embodiment 1, the hottest-point temperature on the device chip was reduced by 15° C. or more. It can be said that the acoustic wave device 20 of Embodiment 1 significantly improves heat dissipation.

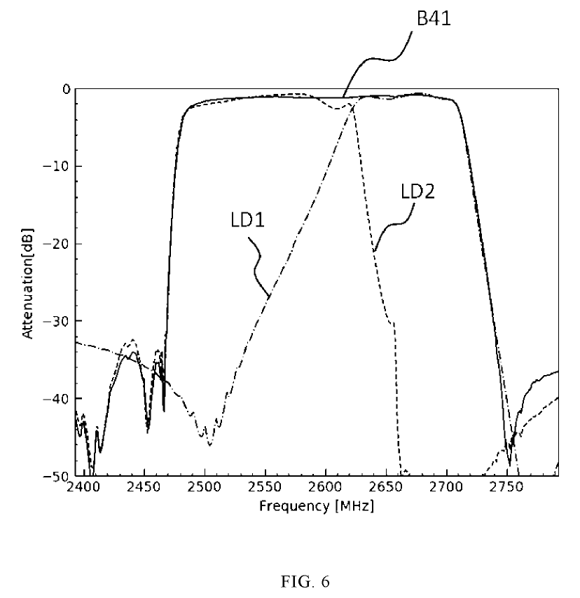

FIG. 6 is a diagram showing transmission characteristics of the acoustic wave device 20 in Embodiment 1. As shown in FIG. 6, the acoustic wave device 20 in Embodiment 1 realizes a transmit/receive filter for a wideband Band 41. Band 41 has a passband from 2496 MHz to 2690 MHz and a relative bandwidth of 7.84%. Since it is used for transmission and reception and therefore requires high power handling, a ladder-type filter was adopted.

To realize a wideband band-pass filter, the passband indicated by the solid line B41 was achieved by combining a ladder-type filter, indicated by the one-dot chain line LD1, which constitutes the high-frequency-side passband, with a ladder-type filter, indicated by the broken line LD2, which constitutes the low-frequency-side passband.

At the initial stage of development, simply configuring with ladder-type filters did not achieve the high power handling required for a transmit/receive band-pass filter. However, by adopting the package substrate configuration of Embodiment 1, heat dissipation was improved and power handling was increased by 0.7 dB, thereby enabling provision of the acoustic wave device 20 that meets the power handling requirements.

According to Embodiment 1 described above, it is possible to provide an acoustic wave device with improved heat dissipation.

### Embodiment 2

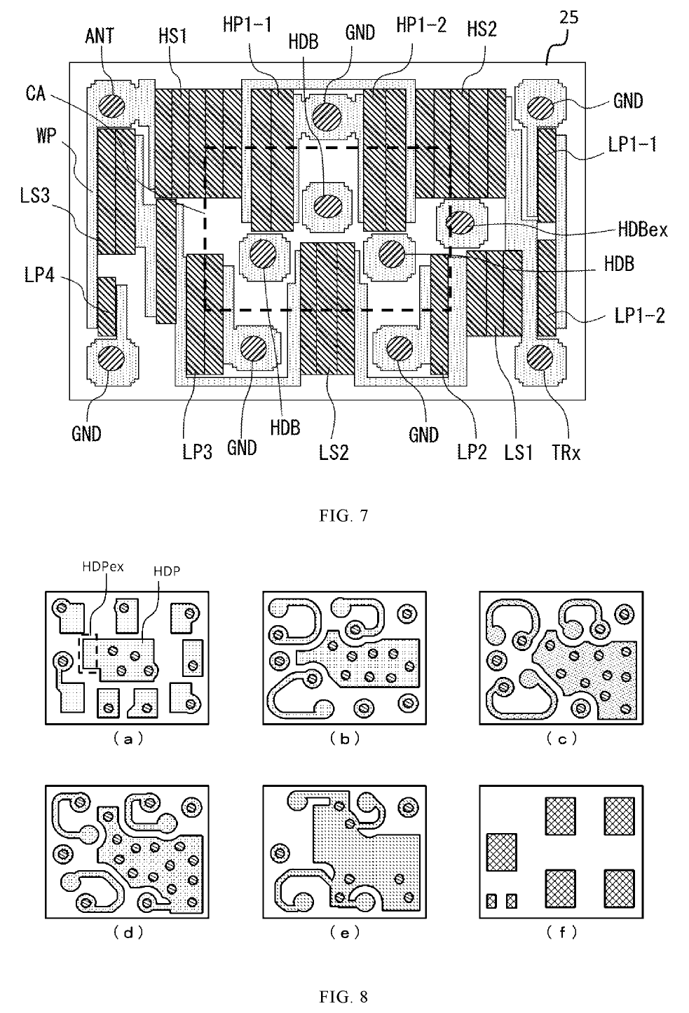

FIG. 7 is a diagram showing an example of the acoustic wave device 20 in Embodiment 2. As shown in FIG. 7, on the device chip 25, a pad for an additional heat dissipation bump HDBex is formed. The pad for the additional heat dissipation bump HDBex is not electrically connected to the wiring pattern WP or to the resonators on the device chip 25. An additional heat dissipation bump HDBex is formed thereon. Since the other configurations are the same as those of the device chip 25 of the acoustic wave device 20 in Embodiment 1, description thereof is omitted.

FIG. 8 is a plan view showing the configuration of each layer of the package substrate of the acoustic wave device 20 in Embodiment 2. As shown in FIG. 8(a), a region HDPex is formed in which the heat dissipation pad HDP is expanded. The additional heat dissipation bump HDBex is bonded to the region HDPex where the heat dissipation pad HDP is expanded. Since the other configurations are the same as those of the package substrate of the acoustic wave device 20 in Embodiment 1, description thereof is omitted.

Thermal analysis of the acoustic wave device 20 of Embodiment 2 showed that the temperature at the hottest point on the device chip was 80.3° C. As described above, the hottest-point temperature on the device chip in Embodiment 1 was 84.5° C. Thus, in the acoustic wave device 20 of Embodiment 2, the hottest-point temperature on the device chip was reduced by 4° C. or more. It can be said that the acoustic wave device 20 of Embodiment 2 further, and markedly, improved heat dissipation.

According to Embodiment 2 described above, it is possible to provide an acoustic wave device 20 with markedly improved heat dissipation.

While certain aspects of at least one embodiment have been described, it should be understood that various alterations, modifications, and improvements will readily occur to those skilled in the art. Such alterations, modifications, and improvements are intended to be part of the present invention and are intended to be within the scope of the present invention.

It should be understood that the embodiments of the methods and apparatus described herein are not limited to application to the details of construction and the arrangement of components set forth in the above description or illustrated in the accompanying drawings. The methods and apparatus may be implemented in other embodiments and may be practiced or carried out in various ways.

Specific implementation examples are provided herein for purposes of illustration only and are not intended to be limiting.

The expressions and terms used in the present invention are for purposes of description and should not be construed as limiting. The use herein of “comprising,” “including,” “having,” “containing,” and variations thereof shall mean inclusion of the items listed thereafter and equivalents thereof as well as additional items.

A reference to “or” (or “and/or”) is to be interpreted such that any of the terms described using “or” may indicate one, more than one, or all of the terms recited.

References to front/back/left/right, top/bottom/up/down, lateral/longitudinal, and obverse/reverse are intended for convenience of description only. Such references do not limit any component of the present invention to any one positional or spatial orientation. Accordingly, the above description and the drawings are merely illustrative.

What is claimed is:

1. An acoustic wave device, comprising:
a package substrate sequentially including a mounting surface, a first inner layer, a second inner layer, and an external connection surface;
a device chip disposed on the mounting surface via a plurality of bumps by flip-chip bonding, wherein the plurality of bumps include a heat-dissipation bump;
a plurality of resonators formed on the device chip and constituting a ladder-type filter;
wherein the mounting surface is provided with a plurality of metal patterns including a heat-dissipation pad connected to the heat-dissipation bump;
wherein the first inner layer is provided with a plurality of metal patterns including a first metal pattern electrically connected to the heat-dissipation pad via at least one via;
wherein the second inner layer is provided with a plurality of metal patterns including a second metal pattern electrically connected to the first metal pattern via at least one via;
wherein the first metal pattern has a larger area than other metal patterns in the first inner layer; and
wherein the second metal pattern has a larger area than other metal patterns in the second inner layer.

2. The acoustic wave device according to claim 1, wherein the heat-dissipation bump is disposed on the device chip so as to be surrounded by the plurality of resonators.

3. The acoustic wave device according to claim 1, wherein the heat-dissipation pad on the mounting surface has a larger area than other metal patterns thereon.

4. The acoustic wave device according to claim 1, wherein the second metal pattern has a larger area than the first metal pattern.

5. The acoustic wave device according to claim 1, wherein the first metal pattern has a larger area than the heat-dissipation pad.

6. The acoustic wave device according to claim 1, wherein the number of vias electrically connecting the first metal pattern and the second metal pattern is greater than that of vias electrically connecting the heat-dissipation pad and the first metal pattern.

7. The acoustic wave device according to claim 1, wherein only the heat-dissipation bump among the plurality of bumps is connected to the heat-dissipation pad.

8. The acoustic wave device according to claim 1, wherein the first metal pattern among the plurality of metal patterns on the mounting surface is electrically connected only to the heat-dissipation pad via a via.

9. The acoustic wave device according to claim 7, wherein, among the plurality of metal patterns of the first inner layer, the second metal pattern is electrically connected via a via only to the first metal pattern.

10. The acoustic wave device according to claim 1, wherein the plurality of bumps include a ground bump electrically connected to the resonators on the device chip;
the plurality of metal patterns formed on the mounting surface include a ground pad connected only to the ground bump;
the plurality of metal patterns formed on the first inner layer include a first inductor pattern electrically connected to the ground pad via a via; and
the plurality of metal patterns formed on the second inner layer include a second inductor pattern electrically connected to the first inductor pattern via a via.

11. The acoustic wave device according to claim 1, wherein: the plurality of bumps include a ground bump electrically connected to the resonators on the device chip;
the plurality of metal patterns formed on the mounting surface include a ground pad to which only the ground bump is connected;
the plurality of metal patterns formed on the first inner layer include a via-receiving metal pattern or an inductor pattern electrically connected to the ground pad via a via; and
the second metal pattern is electrically connected to the via-receiving metal pattern or the inductor pattern via a via.

12. The acoustic wave device according to claim 1, wherein a plurality of the heat-dissipation bumps are formed.

13. The acoustic wave device according to claim 12, wherein at least one of the plurality of heat-dissipation bumps is not electrically connected to any metal pattern on the device chip.

14. The acoustic wave device according to claim 12, wherein at least one of the plurality of heat-dissipation bumps is disposed in a central region of the device chip.

15. The acoustic wave device according to claim 1, wherein only the heat dissipation bump is connected to the heat dissipation pad.

16. The acoustic wave device according to claim 15, wherein the first ladder-type filter and the second ladder-type filter constitute a bandpass filter.

17. The acoustic wave device according to claim 16, wherein some of the plurality of resonators form a high-frequency side passband as multiple series resonators and multiple parallel resonators.

18. The acoustic wave device according to claim 17, wherein others of the plurality of resonators form a low-frequency side passband as multiple series resonators and multiple parallel resonators.

19. A module, comprising an acoustic wave device according to claim 1.

20. The module according to claim 19, wherein the heat-dissipation pad on the mounting surface has a larger area than other metal patterns thereon, the second metal pattern has a larger area than the first metal pattern, and the first metal pattern has a larger area than the heat-dissipation pad.
